(19) United States
(12) Patent Application Publication
(10) Pub. No.: US 2019/0127841 A1
(43) Pub. Date: May 2, 2019

(54) FABRICATION OF SUPERHYDROPHOBIC AND ICEPHOBIC COATINGS BY NANOLAYERED COATING METHOD

(71) Applicant: Nanocoatings, Inc., Rapid City, SD (US)

(72) Inventors: Francis M. Kustas, Rapid City, SD (US); Andrew Benjamin Kustas, Albuquerque, NM (US); Thomas Scott Williams, Long Beach, CA (US); Robert Hicks, Los Angeles, CA (US)

(73) Assignee: Nanocoatings, Inc., Rapid City, SD (US)

(21) Appl. No.: 16/134,667

(22) Filed: Sep. 18, 2018

Related U.S. Application Data
(60) Provisional application No. 62/559,994, filed on Sep. 18, 2017.

(51) Int. Cl. C23C 14/34; C23C 14/10; C23C 14/06; C23C 14/08

(52) U.S. Cl. CPC C23C 14/3471; C23C 14/10; C23C 14/0652; B82Y 30/00; B32B 2311/24; B32B 2307/73; C23C 14/081

(57) ABSTRACT

Nano-multilayered coatings and fabrication methods are disclosed. By exemplary disclosure, a nano-multilayered coating fabricated from sequential depositions on a substrate from an atmospheric-plasma chemical vapor deposition (AP-CVD) source is disclosed. The coating includes a vapor precursor fed to the deposition source, an amorphous oxide layer deposited from the deposition source onto the substrate, and a nanoparticle layer deposited onto the substrate on top of the amorphous oxide layer. A nano-multilayered coating of the amorphous oxide and nanoparticle layers is fabricated from alternating deposition coatings of the amorphous oxide layer and the nanoparticle layer onto the substrate two or more times.

### PRIORITY STATEMENT

This application claims priority to U.S. Provisional Patent Application 62/559,994, filed on Sep. 18, 2017, and entitled Fabrication of Superhydrophobic and Icephobic Coatings by Nanolayered Coating Method, hereby incorporated by reference in its entirety.

### STATEMENT REGARDING FEDERALLY FUNDED RESEARCH

This invention was made with government support under Contract W9113M-08-C-0133, awarded by the U.S. Army/ARSTRAT, Huntsville Ala. The government may have certain rights in this invention.

### TECHNICAL FIELD

The present invention relates to nano-multilayered coatings. More specifically, but not exclusively, the present invention relates to fabrication of layers of nanoparticles and amorphous oxides or amorphous nitrides, which superhydrophobic, icephobic properties, as well as resistance to removal environments (e.g., hot acid and abrasion with hard particles) of interest for anti-tamper protection of electronic components.

### BACKGROUND

Effective superhydrophobic and icephobic coatings that also offer superior anti-tamper protection for electronics and electronic materials preventing, for example, reverse engineering are easily manufactured. Therefore, there is a need to address the present deficiencies in these arts.

### SUMMARY

Therefore, it is a primary object, feature, or advantage of the present invention to improve over the state of the art.

It is a further object, feature, or advantage of the present invention to provide layers of discrete nanoparticles contained between layers of continuous oxide or nitride materials that provide unique properties not-available by either material alone.

It is a still further object, feature, or advantage of the present invention to provide applications for use of these nanolayered materials such as coatings for water-repellent (superhydrophobic) and ice-repellent (icephobic) surfaces on engineering materials.

Another object, feature, or advantage is to provide nano-multilayered coatings for anti-tamper protection of electronic materials to retard or prevent reverse engineering.

Yet another object, feature, or advantage is to provide nano-multilayered coatings that include alternating layers of amorphous oxide and discrete nanoparticles. The amorphous oxide nanolayer can be made continuous, while the nanolayer of nanoparticles can be made discontinuous and the nanoparticles contact the amorphous oxide materials in the nano-multilayer architecture.

In at least one embodiment, a method of fabrication can include use of an atmospheric-plasma (AP) chemical-vapor-deposition (CVD) plasma with a vapor precursor to form a continuous amorphous oxide nanolayer, while nanoparticles are sprayed onto the continuous oxide nanolayer using, for example, an ultrasonically-agitated, air-atomized spray nozzle (UAS) of the nanoparticles in a suitable carrier solvent.

In one aspect, an alternating fabrication method of AP-CVD and UAS can be repeated a large number of times, providing a coating that has x-layers of amorphous oxides by AP-CVD and x−1 layers of ceramic or oxide nanoparticles.

According to another aspect and prior to fabrication of the coating, an AP-CVD plasma, consisting of helium (He) and oxygen (O₂) or Argon (Ar) and O₂, can be used to functionalize and etch the engineering material substrate surface.

In at least one other embodiment, the AP-CVD amorphous oxide layer can be deposited first onto the engineering material substrate, followed by the UAS deposition of the nanoparticle materials, which constitutes a bilayer, and if repeated a large number of times results in a tailored set of material properties, e.g., a larger number of bilayers produce a larger WCA value.

### BRIEF DESCRIPTION OF DRAWINGS

Illustrated embodiments are described in detail below with reference to the attached drawing figures, which are incorporated by reference herein, and where:

FIG. 1 is a schematic drawing of the alternating bilayer (3) architecture depicting a superhydrophobic and icephobic coating consisting of alternating layers of amorphous oxide (2) and nanoparticles (4) fabricated on a substrate (1) in accordance with an illustrative aspect of the present invention;

FIG. 2A is a schematic of deposition sources that can be used to fabricate the nanolayered architecture in accordance with at least one illustrative embodiment;

FIG. 2B is another schematic of deposition sources that can be used to fabricate the nanolayered architecture in accordance with at least one illustrative embodiment;

FIG. 3 are Scanning Electron Microscope (SEM) images showing the distribution of the nanoparticles within the amorphous oxide matrix;

FIG. 4 is a captured image of a water droplet on the surface of a nanolayered coating of the present invention on 304 stainless steel, showing the hydrophobicity of the coating;

FIG. 5 is a captured image of a water droplet on the surface of a nanolayered coating of the present invention on 6061 Al alloy, showing superhydrobicity of the coating;

FIG. 6A is an image of the nanolayered coating of FIG. 5 of the present invention after icing-test, showing retardation/elimination of ice-formation on larger-dimensioned flat surfaces of coated-metal coupon;

FIG. 6B is an image of a conventional coating showing complete ice-formation on larger-dimensioned flat surfaces of coated metal coupon after icing test;

FIG. 7 are images of the multilayered coating of FIG. 1 of the present invention both before and after a jet-etch exposure to 230° C. sulfuric acid for 30-minutes showing no damage or removal of the a-silica (TMTCS precursor)/B₄C multilayered coating; and

FIG. 8 are images of the multilayered coating of FIG. 1 of the present invention both before and after a 1-minute abrasion test against diamond-particle sand-paper showing no damage or removal of the a-silica (TMTCS precursor)/B₄C multilayered coating.

### DETAILED DESCRIPTION

Throughout the disclosure, the terms coating, nanolayer, nanolayered coating, multilayered coating, and nano-multilayered coating(s) are used in reference to the coatings of the present invention. In accordance with an exemplary embodiment of the present invention and prior to fabrication of the a-oxide/hard nanoparticle multilayered coating, an engineering material substrate can be cleaned using, for example, but not limited to the following chemical procedure: 1) ultrasonic agitation in acetone solvent for 5-10 minutes, 2) rinse with methanol solvent, 3) blow-dry in hot air, 4) ultrasonic agitation in hot (≤100° C.) degreaser solution (1 part/7 parts deionized (DI) water) for 5-10 minutes, 5) rinse in DI water, 6) rinse in methanol solvent, 7) blow dry in hot air. Although a method for preparing an engineering material of interest is set forth, the present invention contemplates additional/other steps whether proprietary or conventional for chemically preparing the surface of an engineering material to receive a nanolayered coating of the present invention.

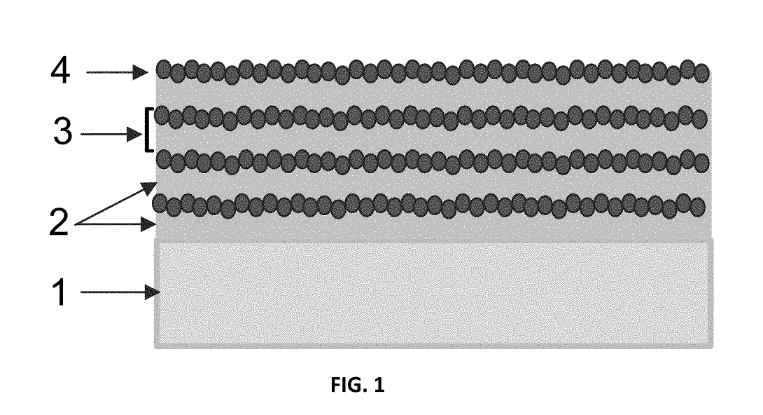

After chemical cleaning, an etch or functionalization of the upper surface of substrate 1 shown in FIG. 1) can be performed, by treating the substrate 1 surface with, for example, an AP-CVD plasma, consisting of He (99.5% purity) and O₂ (99.995% purity) or Ar (99.5% purity) and O₂ ions, in a raster-scanning method to ensure complete processing of the substrate 1 surface. During functionalization, the substrate material can be attached to a hot-plate to heat the substrate material 1 to a temperature of ≥100° C., to remove water from the surface. Functionalization of the substrate 1 surface by the AP-CVD He and O₂ or Ar and O₂ plasma results in a lower water contact angle (WCA) indicating any subsequently-deposited coating material applied to the functionalized surface will wet and more completely cover the engineering material substrate.

Although the proceeding and proceeding processes provide for functionalization of the substrate 1 surface, the present invention contemplates other functionalization steps, processes and plasma agents. Process parameters that can be employed, for example, during the AP-CVD functionalization include, but are not limited to, configuring: 1) AP-CVD shower-head to substrate 1 surface separation distance generally between a range of 5-10 mm, 2) radio frequency (RF) power to AP-CVD shower head generally between 60-100 W, 3) He or Ar gas flow rate generally between 15-30 standard liters per minute (SLM), 4) O₂ gas flow rate generally between 0.3-0.6 SLM, 5) AP-CVD shower head translation rate generally between 10-20 millimeters (mm)/second (s) using a robot, 6) robot program horizontal translation step change generally between 0.5-1.0 mm, and 2) number of AP-CVD passes generally between 1-2.

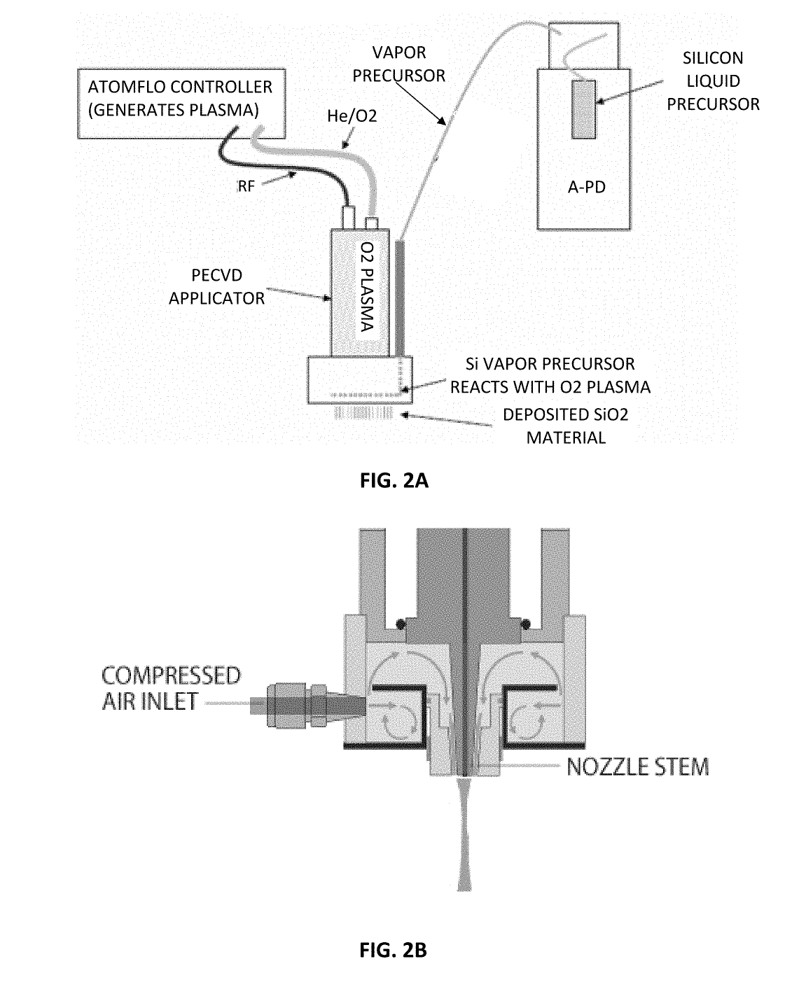

The AP-CVD fabrication method can be used to deposit amorphous oxides 2 shown by way of example in FIG. 1. Deposition occurs by introduction of a vapor from a suitable heated precursor liquid into the AP shower head (see PECVD applicator of atmospheric-plasma chemical vapor deposition system shown in FIG. 2(a)) which emits, in accordance with at least one aspect of the present invention, a He and O₂ or Ar and O₂ plasma with injection of the precursor vapor. Suitable precursor liquids that can be used in a heated bubbler-system (precursor liquid inside container heated by hot water bath) include, but are not limited to:
1) Hexamethyldisiloxane (HMDSO; C₆H₁₈OSi₂),
2) Hexamethyldisilazane (HMDSN; C₆H₁₉NSi₂),
3) 2,4,6,8-Tetramethylcyclotetrasiloxane (TMCTS; (HSiCH₃O₄),
4) Triethoxyfluorosilane (TEOFS; C₆H₁₅FO₃Si),
5) 3,3,3-Trifluoropropyltrichlorosilane (TFPTCS; C₃H₄F₃SiCl₃),
6) Tetramethyldisiloxane (TMDSO; C₄H₁₄OSi₂),
7) Tetramethoxysilane (TMOS; C₄H₁₂O₄Si),
9) Tetraethoxysilane (TEOS; C₈H₂₀O₄Si),
10) (Heptadecafluoro-1,1,2,2-tetrahydrodecyl)trichlorosilane (C₁₀H₄F₁₇SCl₃),
11) Bis(methyldifluorosilyl)ethane (C₄H₁₀F₄Si₂), among others.

Suitable precursors can have a relatively high (e.g., ≥20 mm Hg (torr)) vapor pressure at room temperature, which enables the easy formation of a vapor which can be carried into the AP shower head plasma by an inert gas (e.g., He or Ar) stream. Of the listed precursors above, precursors 1, 2, 4, 6, and 7 all have by way of example acceptable vapor pressures, suggesting their use to form silicon-dioxide. The elements (e.g., silicon (Si)) of the precursor vapor, can react with the O₂ gas in the plasma to form silicon dioxide (or silica; SiO₂). The silica coating can be amorphous, not exhibiting a long-range crystalline structure.

Other amorphous material coatings formed by the AP-CVD method can include, for example, silicon nitride (Si₃N₄) by injection of the HMDSO or HMDS precursor vapors into a He and N₂ or Ar and N₂ plasma. Similarly, amorphous aluminum oxide (Al₂O₃) can be formed by the AP-CVD method by injection of an aluminum (Al) containing vapor precursor, (e.g., Alumatrane; C₆H₁₂NO₄Al) into the He and O₂ or Ar and O₂ plasma.

The present invention contemplates varying process parameters that can be used to deposit the amorphous oxide material 2 shown in FIG. 1 by AP-CVD, which can include but are not limited to, configuring: 1) AP-CVD shower-head to substrate surface separation distance generally between 5-10 mm, 2) radio frequency (RF) power to AP-CVD shower head generally between 60-100 W, 3) He or Ar gas flow rate generally between 15-30 standard liters per minute (SLM), 4) O₂ gas flow rate generally between 0.3-0.6 SLM, 5) HMDS or HMDSO liquid precursor held in a stainless steel (SS) container inside a DI-water bath which can be heated to a temperature of generally 30° C. by a heating-rod immersed in the DI water bath, 6) He or Ar gas sweep-flow to the SS container with the precursor liquid at a rate generally between 0.4-0.6 SLM, 7) AP-CVD shower head translation rate generally between 10-20 millimeters (mm)/second (s) using robot, and 8) a robot program horizontal translation step change generally between 0.5-1.0 mm. In at least one configuration, coverage of the entire substrate surface by the AP-CVD shower head, programmed to move horizontally by 0.5 mm per pass, can be accomplished by using a large number of repeat translation passes. For example, to completely cover a 25 mm (1 inch) wide substrate distance would require 50 translation passes of the AP-CVD head. To completely cover a 25 mm×25 mm area on a substrate can require one X-axis scan of 50 passes and one Y-axis scan of 50 passes, which will take ˜125 seconds to accomplish.

After the AP-CVD process is used to deposit the first amorphous oxide layer, then a ultrasonically-agitated, atomized spray system UAS system shown in FIG. 2(b) can be used, in at least one aspect of the present invention, to spray-deposit a layer of nanoparticles in a solvent carrier. The present invention contemplates varying process parameters that can be used to deposit the nanoparticle layer 4 shown in FIG. 1) by UAS, which can include, but is not limited to, configuring: 1) RF power to the ultrasonic transducer in the syringe pump plunger and spray nozzle generally between 3-6 W, 2) number of turns on the focus mechanism for the spray nozzle generally between 4-8, 3) a weight percent loading generally between 0.1-0.5 weight percent of nanoparticles (e.g., boron carbide (B₄C)) in a suitable solvent (isopropanol (IPA)), 4) a syringe pump flow rate generally between 0.4-1.0 millimeter (ml)/minute (m) to inject the nanoparticle/solvent mixture into the tubing that feeds the ultrasonic spray nozzle, 5) a number of opening turns on the air-nozzle in the nozzle to promote atomization of the spray mixture generally between 4-7, 6) robot translation speed for the spray nozzle translation generally between 10-20 mm/s, 7) a number of passes for the spray nozzle of one (1), 8) spray-nozzle to substrate surface separation distance generally between 12-18 mm (0.47-0.71 in), 9) substrate attached to a hot-plate maintained at a temperature generally ≥100° C., and 10) a robot program horizontal translation step change generally between 3.12-6.25 mm (0.12-0.25 in.). In at least one configuration, coverage of the entire substrate surface by the UAS spray nozzle programmed to move horizontally by 6.25 mm per pass, can be accomplished by using a number of repeat translation passes. For example, to completely cover a 25 mm (1 inch) wide substrate distance would require 4 translation passes of the UAS spray nozzle. To completely cover a 25 mm×25 mm area on a substrate can require four (4) X-axis scans, which will require about 7 seconds.

A bilayer of amorphous oxide and nanoparticles 3 shown in FIG. 1 can be fabricated by alternating depositions from the AP-CVD shower head and UAS nozzle. Repeating the bilayer a selected number of times can produce a nanomultilayered coating that exhibits good adhesion, corrosion-resistance, abrasion-resistance, and superhydrophobic/icephobic behavior.

### EXAMPLES

The present invention is described below by way of examples. However the present invention is not limited thereto the examples described below.

### Example 1

An aluminum alloy (6061 Al) coupon of selected size 50.8 mm (2 in) wide×101.6 mm (4 in) long×6.35 mm (0.25 in) thick was cleaned according to the chemical-cleaning and He & O₂ ionized-gas plasma-etch/functionalization procedure described below.

In at least one of the examples of the present invention, a chemical cleaning procedure can consist of, but is not limited to: 1) ultrasonic agitation in acetone solvent for ˜5-minutes, 2) rinse with methanol solvent, 3) blow-dry in hot air, 4) ultrasonic agitation in hot (generally ≤100° C.) degreaser solution (1 part/7 parts deionized (DI) water) for ˜5-minutes, 5) rinse in DI water, 6) rinse in methanol solvent, 7) blow dry in hot air.

After chemical cleaning and before AP-CVD etch/functionalization, SS substrates are mechanically-attached to a hot-plate to heat the substrate material to a temperature of 100° C., to remove or otherwise evaporate water from the surface.

Stainless steel coupons mounted on the hot-plate can be plasma-etched/functionalized by treating the substrate surface with the AP-CVD plasma, consisting of, for example, He (99.5% purity) and O₂ (99.995% purity) or Ar (99.5% purity) and O₂ ions, in a raster-scanning method to ensure complete processing of the substrate surface. Process parameters that can be employed during the AP-CVD functionalization include, but are to limited to, configuring: 1) AP-CVD shower-head to substrate surface separation distance of 5 mm, 2) radio frequency (RF) power to AP-CVD shower head of 100 W, 3) He gas flow rate of 25 standard liters per minute (SLM), 4) O₂ gas flow rate of 0.3 SLM, 5) AP-CVD shower head translation rate of 20 millimeters (mm)/second (s) using robot, 6) robot program horizontal translation step change of 0.5 mm, and 2) number of AP-CVD passes of 2.

In accordance with at least one exemplary aspect of the present invention, the AP-CVD fabrication method was used to deposit amorphous oxides by introduction of a vapor from a hexamethyldisilazane (C₆H₁₉NSi₂) (or HMDS) liquid precursor heated to 30° C., while contained in a SS container housed in a heated-water bath. The vapor from the HMDS precursor was swept by He gas, maintained at a flow rate of 0.4 SLM, into the AP shower head which emits a He and O₂ plasma. The element (e.g., silicon (Si)) of the HMDS precursor vapor reacted with the O₂ gas ions in the plasma to form silicon dioxide (or silica; SiO₂). The silica coating is amorphous, as confirmed by x-ray diffraction (XRD), and therefore does not exhibit a long-range crystalline structure.

At least some specific process parameters used to deposit the amorphous oxide material by AP-CVD can include, but are not limited to, configuring: 1) AP-CVD shower-head to substrate surface separation distance of 5 mm, 2) radio frequency (RF) power to AP-CVD shower head of 100 W, 3) He or Ar gas flow rate of 25 standard liters per minute (SLM), 4) O₂ gas flow rate of 0.3 SLM, 5) HMDS liquid precursor held in a stainless steel (SS) container inside a DI-water bath which can be heated to a temperature of 30° C. by a heating-rod immersed in the DI water bath, 6) He gas sweep-flow to the SS container with the precursor liquid at a rate of 0.4 SLM, 7) AP-CVD shower head translation rate of 20 millimeters (mm)/second (s) using robot, and 8) robot program horizontal translation step change of 0.5 mm.

In accordance with at least one method of the present invention, ultrasonic atomized spray (UAS) is used to spray-deposit a layer of nanoparticles in a solvent carrier. Process parameters used to deposit the nanoparticle layer UAS can include, but are not limited to, configuring: 1) RF power to the ultrasonic transducer in the syringe pump plunger and spray nozzle of 3 W, 2) number of turns on the focus mechanism for the spray nozzle of 4, 3) a weight percent loading of 0.1% of nanoparticles (e.g., 35 nm boron carbide (B₄C)) in a suitable solvent (isopropanol (IPA)), 4) a syringe pump flow rate of 0.8 millimeter (ml)/minute (m) to inject the nanoparticle/solvent mixture into the tubing that feeds the ultrasonic spray nozzle, 5) number of opening turns on the air-nozzle in the nozzle to promote atomization of the spray mixture of 6.25, 6) robot translation speed for the spray nozzle translation of 10 mm/s, 7) number of passes for the spray nozzle of 1, 8) spray-nozzle to substrate surface separation distance of 18 mm (0.71 in), 9) robot program horizontal translation step change of 6.25 mm (0.25 in.).

The above two (2) deposition processes were performed sequentially to produce a bilayer of material: 1) AP-CVD of a-silica and 2) UAS of B₄C nanoparticles. This sequence was performed a total of six (6) times with a final cap layer of a-silica by AP-CVD, resulting in a total number of 7 individual layers.

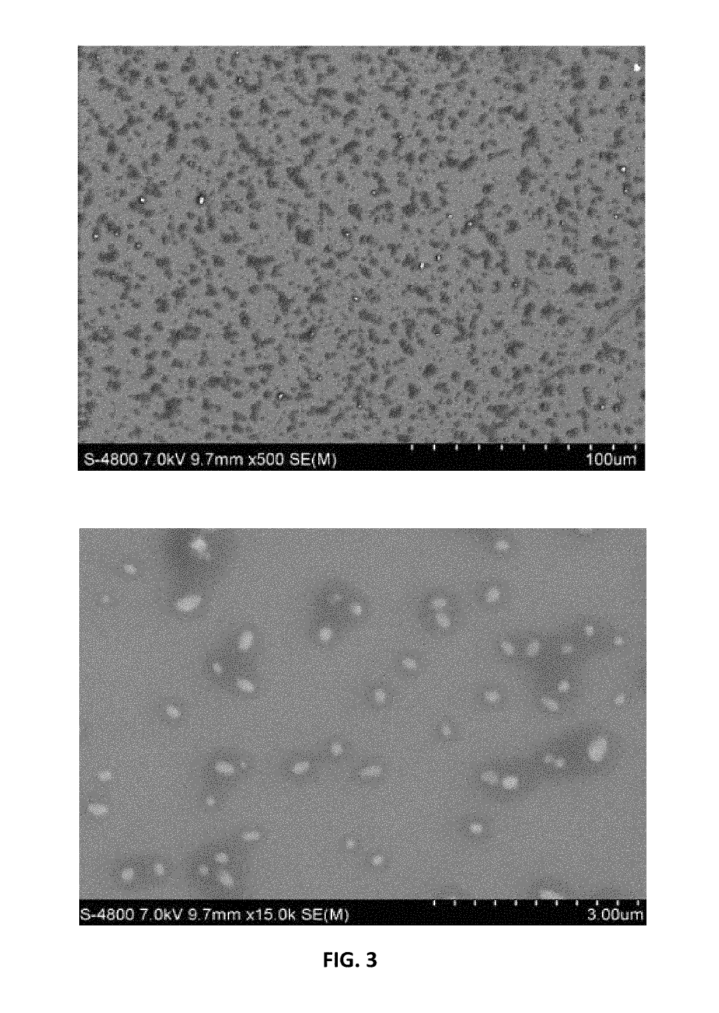

Scanning electron microscope (SEM) images of the surface of the fabricated nanolayered material showed the uniform distribution of the B₄C nanoparticles, as shown in both images of FIG. 3. A tape-peel test method, per ASTM D3359-09 (but without the scribe-cut pattern), revealed only a small amount of B₄C nanoparticle removal, indicating the inorganic a-silica layer was acting as a glue agent to keep the nanoparticles attached within the coating.

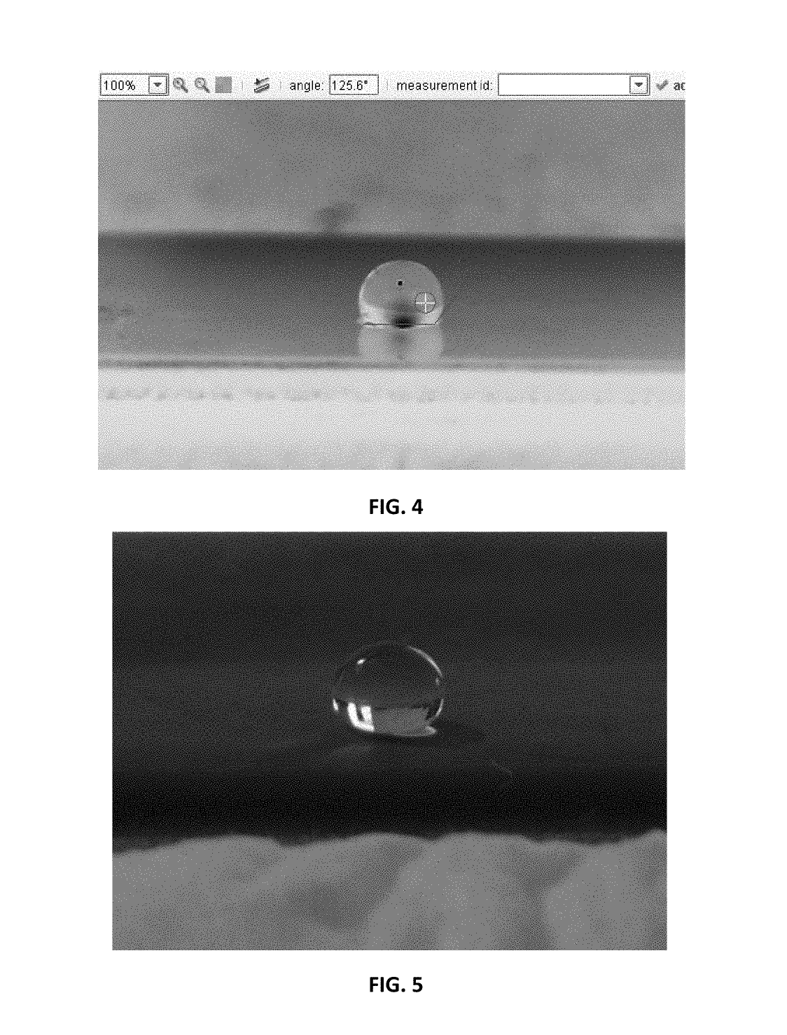

Water contact angles were measured using a conventional digital camera and the software program (i.e., Simages). FIG. 4 show an image of a water droplet and the corresponding water contact angle (WCA) measurement for the 7-layer a-silica/B₄C nanoparticle coating. The average WCA for four measurements was 125.5°. From these measurement values, the WCAs for this nano-multilayered coating fall within the hydrophobic regime; that is any coating having WCAs greater than 90° as measured tangentially to the outer surface of the water droplet.

### Example 2

Another exemplary aspect of the present invention includes fabricating one or more nano-multilayered coatings. For example, a second a-SiO₂/B₄C nano-multilayered coating, fabricated with a greater number of bilayers (e.g., 11 a-silica and 11 B₄C nanoparticles) capped with a final a-silica layer (total of 23 layers) exhibited a larger WCA as shown in FIG. 5, although not qualitatively measured. This 23-layer coating exhibited water droplet run-off from the coated surface, when the coated substrate was slightly tilted by an angle generally equal to or greater than about 2 degrees. This result suggests increasing the number of a-SiO₂/B₄C bilayers produces a coating with greater hydrophobicity, presumably due to a larger volume fraction of B₄C nanoparticles.

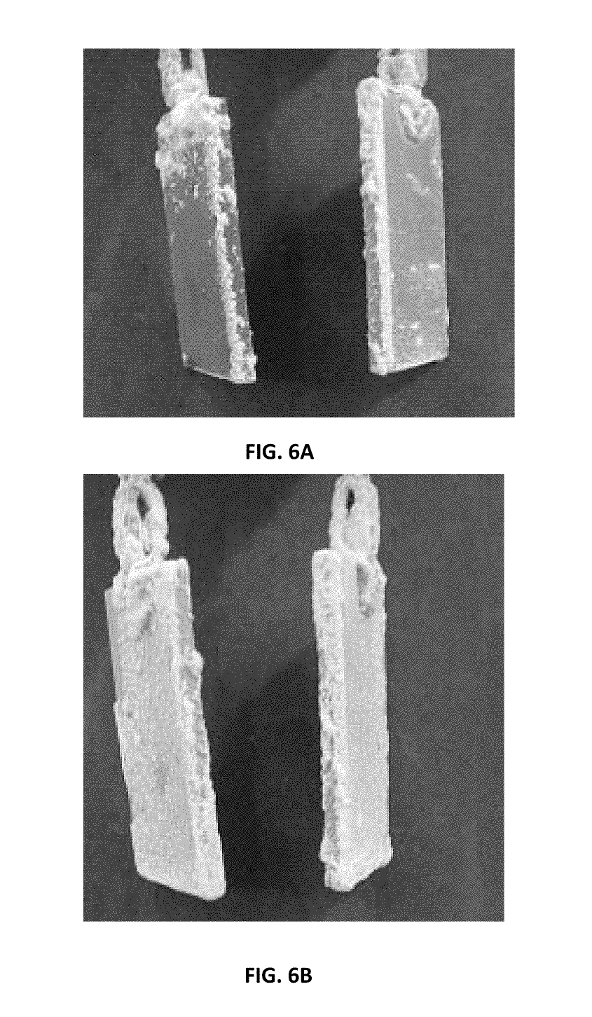

The same nano-multilayered coating as above while on 6061-Al was subjected to an icing exposure using the following test conditions: 1) impact angle of air/water stream: 30°, 2) air flow rate: 151.2 gm/second (20 lbs/min), 3) inlet temperature: 20° C., 4) inlet pressure: 137.9 kPa (20 psia), and 5) water flow rate: 0.166 gm/second (0.022 lbs/min). FIGS. 6(a)-(b) are photographs of coated 6061Al coupons after icing exposure. FIG. 6(a) shows the nano-multilayered superhydrophobic coating shown in FIG. 5, while FIG. 6(b) shows a test coating of unknown (i.e., conventional) composition. The superhydrophobic coating in FIG. 6(a) shows much less icing tendency than the conventional coating shown in FIG. 6(b) after comparable icing exposures.

### Example 3

It is desirable to protect electronic components from intrusion and tampering which can be used to remove program sensitive information. Contextually speaking, “anti-tamper resistant” generally refers to a surface that either: 1) cannot be easily removed by conventional removal methods (e.g., hot acid etch or hard-particle abrasion that occurs during sanding) or 2) one that if removed would result in the underlying electronic components being damaged beyond use/repair. The nano-multilayered coating described in FIG. 1 can produce an anti-tamper resistant surface. In one exemplary embodiment of the coating design shown in FIG. 1, 11 layers of a-silica (using 2,4,6,8-Tetramethylcyclotetrasiloxane (TMTCS) precursor) and 10 layers of B₄C nanoparticles (0.2 weight percent in isopropanol (IPA), were prepared by sequential deposition of a-silica then B₄C onto a passivated (Si₃N₄ coated) silicon wafer, repeating this bilayer architecture a total of 10 times, followed by a top layer of a-silica. The total number of individual coating layers, at least by way of example, was therefore 21.

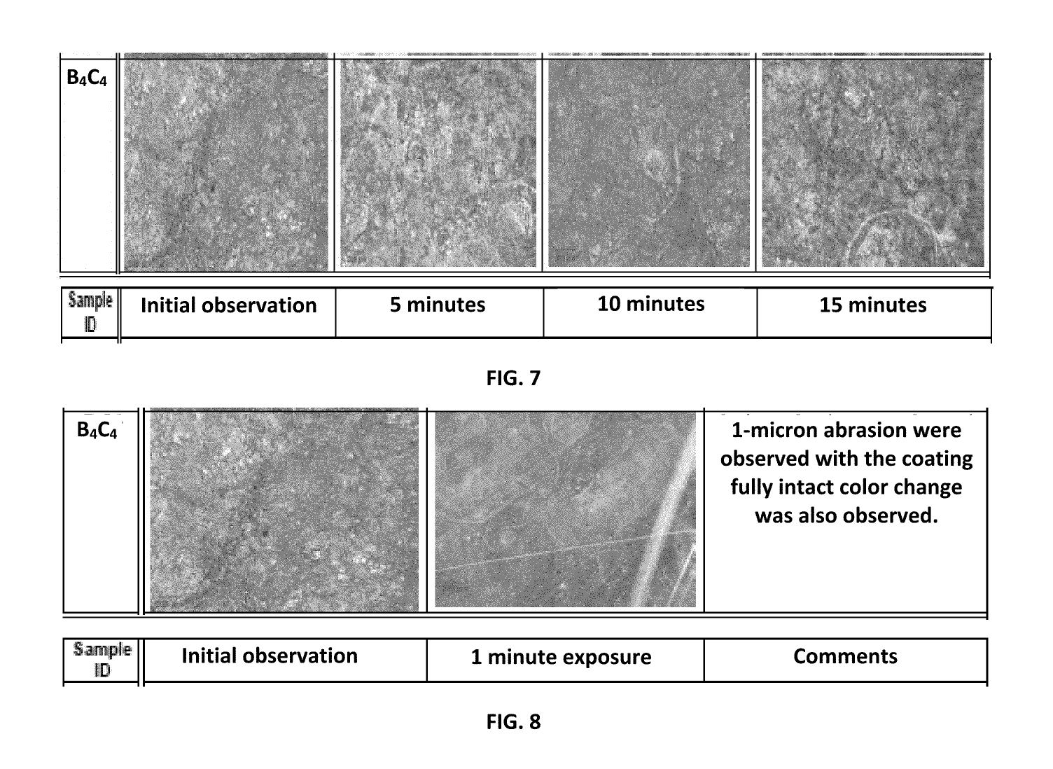

The same nano-multilayered coating described above can provide resistance to hot (e.g., 260° C.) sulfuric-acid jet-etch for a 15-minute duration, without coating damage or removal (FIG. 7). In a similar manner, the same nano-multilayered coating as above can survive, without coating removal, a 1-minute exposure to a wet diamond-particle sanding operation (FIG. 8). It is observed that some scratching of the coating surface can be produced since the diamond-particles are harder than the boron-carbide particles contained in the tamper-resistant coating, but the coating remained intact.

The illustrative embodiments are not to be limited to the particular embodiments described herein. In particular, the illustrative embodiments contemplate numerous variations in the type of ways in which embodiments may be applied. The foregoing description has been presented for purposes of illustration and description. It is not intended to be an exhaustive list or limit any of the disclosure to the precise forms disclosed. It is contemplated that other alternatives or exemplary aspects are considered included in the disclosure. The description is merely examples of embodiments, processes or methods of the invention. It is understood that any other modifications, substitutions, and/or additions may be made, which are within the intended spirit and scope of the disclosure. For the foregoing, it can be seen that the disclosure accomplishes at least all of the intended objectives.

The previous detailed description is of a small number of embodiments for implementing the invention and is not intended to be limiting in scope. The following claims set forth a number of the embodiments of the invention disclosed with greater particularity.

What is claimed is:

1. A method for fabricating nano-multilayered coatings by sequential deposition, comprising:
providing an atmospheric-plasma chemical vapor deposition (AP-CVD) source and a substrate;
feeding a vapor precursor to the source;
depositing an amorphous oxide layer onto the substrate;
depositing a nanoparticle layer onto the substrate on top of the amorphous oxide layer; and
alternating deposition coatings of the amorphous oxide layer and the nanoparticle layer onto the substrate two or more times for fabricating a nano-multilayered coating of the amorphous oxide and nanoparticle layers.

2. The method of claim 1, wherein the amorphous oxide layer comprises at least one of silicon dioxide, silicon nitride, aluminum oxide, and zirconium oxide.

3. The method of claim 1, further comprising:
ultrasonically agitating and atomizing the nanoparticle layer for depositing onto the substrate.

4. The method of claim 1, further comprising:
functionalizing a surface of the substrate with a plasma from the source comprising at least one of Helium or Argon or Silicon and Oxygen or Nitrogen gas.

5. The method of claim 4, further comprising:
injecting the vapor precursor into the plasma.

6. The method of claim 1, wherein the vapor precursor has at least vapor pressure at room temperate greater than 20 mm Hg (torr).

7. The method of claim 1, wherein the nano-multilayered coating has a water droplet contact angle at least greater than 90° for hydrophobic behavior and at least greater than 150° for superhydrophobic behavior based on the number of alternating deposition coatings.

8. The method of claim 1, wherein the nanoparticles are at least smaller than 50 nm.

9. The method of claim 1, wherein the nanoparticles comprise nanoparticles from one or more carbide groups or one or more oxide groups.

10. A nano-multilayered coating fabricated from sequential depositions on a substrate from an atmospheric-plasma chemical vapor deposition (AP-CVD) source, comprising:
a vapor precursor fed to the deposition source, the vapor precursor having at least a vapor pressure at room temperate greater than 20 mm Hg (torr);
an amorphous oxide layer deposited from the deposition source onto the substrate;
a nanoparticle layer deposited onto the substrate on top of the amorphous oxide layer; and
a nano-multilayered coating of the amorphous oxide and nanoparticle layers fabricated from alternating deposition coatings of the amorphous oxide layer and the nanoparticle layer onto the substrate two or more times.

11. The nano-multilayered coating of claim 10, wherein a surface of the substrate is prepared for deposition etching or functionalizing with an AP-CVD plasma consisting of Argon or Helium and Oxygen or Nitrogen gas.

12. The nano-multilayered coating of claim 10, wherein the vapor precursor comprises silicon-dioxide derived from a family of liquid reagents, including hexamethyldisiloxane (C₆H₁₈OSi₂) (HMDSO) or hexamethyldisilazane (C₆H₁₉NSi₂) (HMDS).

13. The nano-multilayered coating of claim 10, wherein the nanoparticle layer comprises nanoparticles from one or more carbide groups, or one or more oxide groups.

14. The nano-multilayered coating of claim 10, wherein the amorphous oxide layer comprises at least one of silicon dioxide, silicon nitride, aluminum oxide, and zirconium oxide.

15. The nano-multilayered coating of claim 10, wherein the nanoparticle layer is ultrasonically agitated and atomized prior to deposition onto the substrate.

16. The nano-multilayered coating of claim 10, wherein the nano-multilayered coating has a water droplet contact angle at least greater than 90° for hydrophobic behavior and at least greater than 150° for superhydrophobic behavior based on the number of alternating deposition coatings.

17. The nano-multilayered coating of claim 10, wherein the nanoparticle layer comprises nanoparticles of at least 50 nm or smaller.

18. The nano-multilayered coating of claim 10, wherein the substrate comprises an electronic component having one or more electrical components and the coating comprises an anti-tamper layer on the electronic component.

19. The nano-multilayered coating of claim 10, wherein the substrate comprises an engineered layer having one or more engineered components and the coating comprises a water-repellent (superhydrophobic) coating or an ice-repellent (icephobic) coating on a surface of the engineered layer.
